(19) United States
(12) Patent Application Publication
(10) Pub. No.: US 2014/0304464 A1
(43) Pub. Date: Oct. 9, 2014

(54) METHODS AND SYSTEMS FOR PERFORMING DEDUPLICATION IN A DATA STORAGE SYSTEM

(71) Applicant: LSI CORPORATION, San Jose, CA (US)

(72) Inventor: Luca Bert, Cumming, GA (US)

(73) Assignee: LSI Corporation, San Jose, CA (US)

(21) Appl. No.: 13/855,814

(22) Filed: Apr. 3, 2013

(51) Int. Cl. G06F 3/06; G11C 7/10

(52) U.S. Cl. CPC G06F 3/0641; G11C 7/1072; G06F 3/0689; G06F 3/0619
USPC 711/105

(57) ABSTRACT

A dedupe cache solution is provided that uses an in-line signature generation algorithm on the front-end of the data storage system and an off-line dedupe algorithm on the back-end of the data storage system. The in-line signature generation algorithm is performed as data is moved from the system memory device of the host system into the DRAM device of the storage controller. Because the signature generation algorithm is an in-line process, it has very little if any detrimental impact on write latency and is scalable to storage environments that have high IOPS. The back-end deduplication algorithm looks at data that the front-end process has indicated may be a duplicate and performs deduplication as needed. Because the deduplication algorithm is performed off-line on the back-end, it also does not contribute any additional write latency.

### CROSS-REFERENCE TO RELATED APPLICATIONS

This application is a nonprovisional application that claims priority to and the benefit of the filing date of a provisional application that was filed on Mar. 15, 2013, having application Ser. No. 61/791,083 and entitled “METHOD AND SYSTEM FOR PERFORMING DEDUPLICATION IN A DATA STORAGE SYSTEM,” which is hereby incorporated by reference herein in its entirety.

### TECHNICAL FIELD OF THE INVENTION

The invention relates generally to data storage systems and, more particularly, to methods and systems for performing deduplication in a data storage system.

### BACKGROUND OF THE INVENTION

A storage array or disk array is a data storage device that includes multiple hard disk drives (HDDs), solid state disks (SSDs) or similar persistent storage units. A storage array can allow large amounts of data to be stored in an efficient manner. A server or workstation may be directly attached to the storage array such that the storage array is local to the server or workstation. FIG. 1 illustrates a block diagram of a typical data storage system 2. The system 2 includes a host system 3, a storage controller 4, and a peripheral interconnect (PCI) or PCI Express (PCIe) bus 5. The storage controller 4 includes a central processing unit (CPU) 6, a controller dynamic random access memory (DRAM) device 7, a SSD cache memory device 8, and an I/O interface device 9. The I/O interface device 9 is configured to perform data transfer in compliance with known data transfer protocol standards, such as the Serial Attached SCSI (SAS) standard, the Serial Advanced Technology Attachment (SATA) standard, or the Nonvolatile Memory Host Controller Interface Express (NVMe) standard. The I/O interface device 9 controls the transfer of data to and from multiple physical disks (PDs) 10, which are typically either HDDs or SSDs.

The storage controller 4 communicates via the PCI bus 5 with a system CPU 11 and a system memory device 12. The system memory device 12 stores software programs for execution by the system CPU 11 and data. A portion of the system memory device 12 is used as a command queue 13. During a typical write action, the system CPU 11 runs a memory driver software stack 14 that stores commands and data in the command queue 13. When the memory driver 14 stores a command in the command queue 13, it notifies the memory controller 4 that a command is ready to be executed.

When the controller CPU 6 is ready to execute a command, it moves the command and the associated data via the bus 5 from the system queue 13 into a command queue of the controller DRAM device 7 and issues a completion interrupt to the host system 3. The controller CPU 6 checks the SSD cache memory device 8 to determine whether or not the write data is already contained in the cache memory device 8, i.e, to determine whether a cache hit or miss has occurred. If the data is already in the cache memory device 8 (cache hit), the controller CPU 6 skips writing the data. If the data is not already in the cache memory device 8 (cache miss), the controller CPU 6 temporarily stores the data in the cache memory device 8 and subsequently causes the data to be written to one or more of the PDs 10 via the I/O interface device 9.

As usage of SSDs for storage caching becomes more and more viable, a new set of challenges has arisen that requires a new approach to implementing cache. One approach to maximizing cache value is to improve the hit rate by growing the size of cache. This is a viable, but expensive, approach. The opposite approach is to keep the size of cache constant, but “shrink” the data that is cached. The latter approach is a very promising approach as it comes at no capital expenditure (i.e., it uses existing solutions). However, shrinking data presents new challenges because not all data lends itself to being shrunk in the same way or in a constant way. For this reason, the assignee of the present application has developed a family of cache solutions that are sometimes referred to as “Elastic Cache” because the size of cache memory grows and shrinks like an elastic band, based on the nature of the data.

There are several approaches to designing elastic cache solutions, one of which is known as deduplication, or simply dedupe. Dedupe is used to further reduce the cached data set. A number of different dedupe algorithms are currently used in the data storage industry for this purpose. In general, dedupe is a process of eliminating duplicate copies of data by identifying repeating chunks, or byte patterns, of data and storing a reference for duplicate data chunks rather than storing the duplicate data chunk. Because byte patterns can repeat a large number of times (hundreds or thousands of times), deduplication greatly reduces the amount of data that must be stored in cache memory.

Dedupe solutions should meet certain criteria. In particular, dedupe solutions should: (1) have very low (theoretically zero) write latency impact; (2) be capable of working in storage environments that have a high number of input-output operations per second (IOPS); and (3) be capable of reducing the number of writes so as not to detrimentally impact the life expectancy of the SSDs. With respect to criteria (1), this is the key metric for caches and a major limitation for most dedupe solutions, which typically add significantly large latency. With respect to criteria (2), the dedupe solution should be capable of work in an environment where the number of IOPS is greater than 100,000, or even greater than 1,000,000. Many current dedupe solutions either consume so much computing power that they cannot be scaled up to such loads or are designed to work in a “quiet” environment on semi-static data, which is never the case with cache memory. With respect to criteria (3), it is important to reduce the number of writes to SSD cache because writes impact SSD endurance. Reducing the number of writes can extend the life of the SSD or allow lower-grade devices to be used with same life expectancy.

Of the above criteria, criteria (1) and (2) are key requirements for cache dedupe and are the criteria that existing solutions have the most difficulty meeting. Criteria (3), if met, is an added benefit of dedupe. Dedupe solutions have been in existence for quite some time and there are a variety of solutions. In the storage space environment, dedupe solutions are often used for secondary storage (e.g., backup), but there are also dedupe solutions that are applied to primary storage. The use of dedupe solutions with cache storage is relatively recent, and, due to the nature of cache, the existing cache dedupe solutions are not very efficient.

There are generally two models for cache dedupe solutions, namely, in-line dedupe and off-line dedupe. Both models have major limitations. With in-line dedupe, there are never write duplicates. Generally, all IOs go through a dedupe engine that determines if a copy of the data exists, and if so, a reference is added to cache memory and the write is skipped. This model is by far the best, but requires a large amount of front-end computation. If the dedupe engine is not hardware (HW)-accelerated, the write latency that is added is several times larger than the target write latency, which does not meet above criterion (1). The in-line dedupe model also consumes so much computing power that running it at a rate of 100K IOPS or more is generally not viable within the typical HW budget, which does not meet criterion (2). On the other hand, the in-line dedupe model greatly reduces the number of writes to cache, which meets above criterion (3).

With the off-line dedupe model, all data is written, and duplicate data is removed at a later time, i.e., off-line. In general, data is written at wire speed (meets above criteria (1) and (2), but does not meet above criteria (3). A backend “lazy process” is performed off-line that scrubs the storage looking for duplicate data to remove. The off-line model is suitable for backup and secondary storage where data is “idle” for most of time after being written and therefore allows for such process. The off-line model is generally unsuitable for cache data, which is never idle and changes at very high rates (e.g., 100K+IOPS). For this reason, the off-line model is generally impractical for a cache because of the dynamic nature of the cache.

Dedupe is sometimes described as data compression due to fact that it reduces the amount of data. However, while compression and dedupe produce similar results (less end data), compression generally is performed on short range data (e.g., a single command) where the data can be compressed by lossless technologies, whereas dedupe works on long range data (e.g., a data set that can be 1,000's or 1,000,000s IO operations apart in an IO pattern). Compression generates a new smaller data pattern, whereas dedupe uses the original data pattern, but provides pointers to aliases.

Accordingly, a need exists for a cache dedupe solution that meets above criteria (1), (2) and (3).

### SUMMARY OF THE INVENTION

The invention is directed to a data storage system, a storage controller for use in a data storage system, and dedupe methods for use in data storage systems and storage controllers. The data storage system comprises a host system and a storage controller. The host system comprises a system processor and a system memory device. The storage controller comprises a controller processor, a controller DRAM device, and an SSD cache device. A bus interconnects the host system with the storage controller.

The data storage system performs a deduplication process comprising a front-end process and a back-end process. The front-end process is an in-line process that is performed as data to be written is moved from the system memory device via the bus into the controller DRAM device. The front-end process comprises performing a signature generation algorithm on the data to generate a signature for the data and associating the signature with a respective count value. The back-end process comprises a deduplication process that uses the count value to perform deduplication.

In accordance with an embodiment, the controller processor of the storage controller is configured to perform a deduplication process comprising a front-end process and a back-end process. The front-end process is an in-line process that is performed as data to be written is moved from a system memory device of the host system into the controller DRAM device. The front-end process comprises performing a signature generation algorithm on the data to generate a signature for the data and associating the signature with a respective count value. The back-end process comprises a deduplication process that uses the count value to perform deduplication.

In accordance with an embodiment, the method comprises:

in a system memory device of the host system, storing data;

in the data storage system, moving the data from the system memory device into a DRAM device of a storage controller of the data storage system;

as the data is moved from the system memory device into the controller DRAM device, performing an in-line signature generation process on the data to generate a signature for the data and associating the signature with a respective count value; and

after the signature generation process has been performed, performing a back-end deduplication process that uses the count value to perform deduplication.

In accordance with an embodiment, a non-transitory computer-readable medium (CRM) having a computer program stored thereon is provided. The computer program comprises computer code for execution by one or more processors of a storage controller of a data storage system for performing deduplication in the data storage system. As data is moved from a system memory device of a host system of the data storage system into a DRAM device of the storage controller, an in-line signature generation process is performed on the data to generate respective signatures for respective data. The computer program for execution by one or more processors of the storage controller comprises a front-end code portion and a back-end code portion. The front-end code portion includes computer code that associates each respective signature with a respective count value. The back-end code portion includes computer code that performs a back-end deduplication process that uses the count values to perform deduplication.

These and other features and advantages of the invention will become apparent from the following description, drawings and claims.

### BRIEF DESCRIPTION OF THE DRAWINGS

FIG. 1 illustrates a block diagram of a known data storage system that implements SSD cache memory in the storage controller.

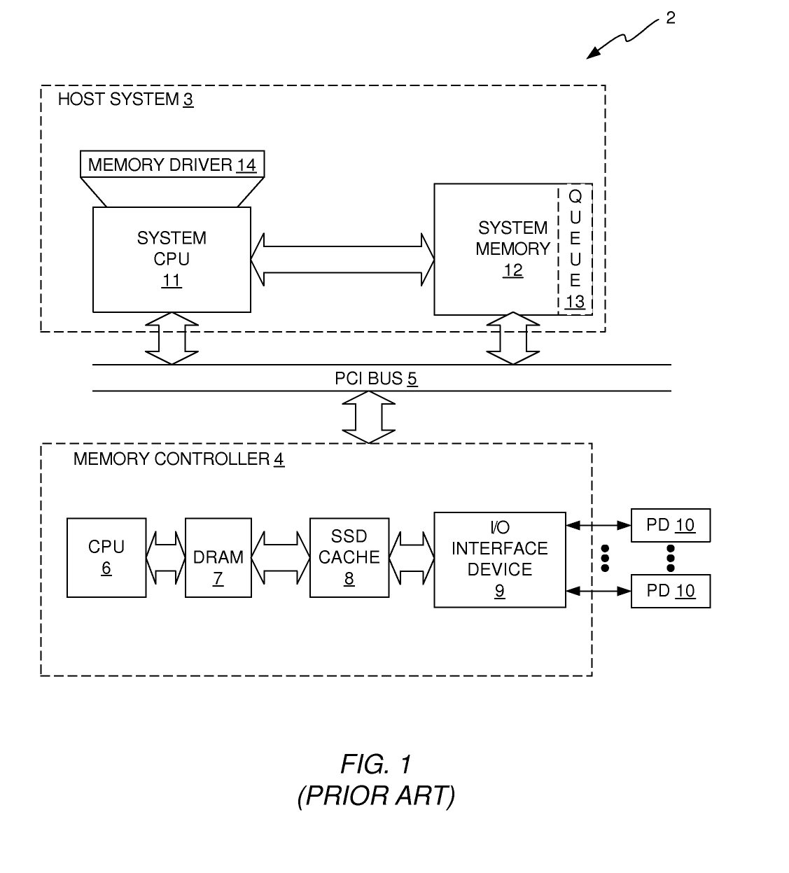

FIG. 2 illustrates a block diagram of a data storage system in accordance with an illustrative embodiment that implements a dedupe solution that is split between the front end and the back end of the data storage system.

FIG. 3 illustrates a flow diagram that represents the front-end portion of the dedupe process in accordance with an illustrative embodiment.

FIG. 4 illustrates a flow diagram that represents the back-end portion of the dedupe process in accordance with an illustrative embodiment.

FIG. 5 illustrates a block diagram of a lookup table (LUT) and an array of count values that are used in accordance with an illustrative embodiment to perform the front-end and back-end dedupe processes.

FIG. 6 illustrates a flow diagram that demonstrates the front-end algorithm described above with reference to FIG. 5.

FIG. 7 illustrates a flow diagram of a first portion of the back-end algorithm in accordance with an illustrative embodiment, which uses the count values stored in the array shown in FIG. 5 to determine whether data stored in the DRAM device of the storage controller is to be moved into the SSD cache device of the storage controller.

FIG. 8 illustrates a flow diagram of the off-line back-end process in accordance with an illustrative embodiment that includes a modified dedupe algorithm that uses the count values stored in the array shown in FIG. 5 to manage the back-end dedupe process.

### DETAILED DESCRIPTION OF AN ILLUSTRATIVE EMBODIMENT

In accordance with illustrative embodiments described herein, a dedupe cache solution is provided that uses an in-line signature generation algorithm on the front end of the data storage system and an off-line dedupe algorithm on the back end of the data storage system. The front-end and back-end dedupe algorithms are stitched together in a way that provides very high dedupe efficiency. The in-line, front-end process includes a signature generation algorithm that is performed on the data as it is moved from the system memory device of the host system into the DRAM device of the storage controller. In addition, the front-end process indicates which signatures are associated with data that may be duplicates. Because the front-end process is an in-line process, it has very little, if any, detrimental impact on write latency and is scalable to storage environments that have high IOPS. The back-end deduplication algorithm looks at data that the front-end process has indicated may be a duplicate and performs deduplication as needed. Because the back-end deduplication algorithm is performed off-line, it does not contribute any additional write latency.

Because performance is paramount, the dedupe cache solution described herein does not necessarily seek to obtain 100% deduplication, as the cost of such an algorithm might detrimentally impact write performance. Rather, one goal of the dedupe cache solution described herein is to obtain a tunable algorithm that can balance dedupe quality with the performance cost of performing dedupe. In other words, it is believed that missing some duplicates will still produce satisfactory results and that the cost of eliminating all duplicates may be too high.

Another goal of the illustrative embodiment is to minimize write latency, which is accomplished in part by decoupling the front-end dedupe processing from the back-end dedupe processing. The term “front-end processing,” as that term is used herein, is intended to denote the processing occurs from the time of IO generation in the host system to the time that data are safely stored in the controller DRAM device and the IO is completed. The term “back-end processing,” as that term is used herein, is intended to denote the processing that is performed to move data from the controller DRAM device into the SSD cache device and the back-end deduplication processing that is performed to remove duplicates from the SSD cache device.

The signature generation part of the front-end process will typically be performed by a hash engine of some type that creates a hash of the data being written. The hash is a signature, and so the terms “hash” and “signature” are used interchangeably herein. The dedupe process of the back-end process looks at data that has the same hash as possible duplicates and manages them (e.g., redirects duplicates, recreates duplicates during writes, flushes duplicates, etc). The signature generation process is performed in-line when a write command is issued. As indicated above, the reason for performing this process as an in-line process is that it adds very little, if any, write latency. If a direct memory access (DMA) engine is implemented in the storage controller for moving commands and data from system memory into the DRAM device of the storage controller, the DMA engine may be used to generate the signatures. DMA engines are widely used in storage controllers, and many DMA engines are capable of cryptographic encoding. In such cases, because the data are flowing through the DMA engine, it is capable of generating the hash signature in-line on the fly. Thus, there is virtually no added write latency (above criterion (1) is met).

Instead of using a DMA engine to perform signature generation, the signature generation process may be performed programmatically, e.g., by the system memory driver program. The system memory driver program is typically running on the most powerful processor in the system (i.e., the host CPU), and therefore any additional latency will be as low as possible. It should be noted that the signature thus obtained may or may not be the final dedupe hash as this will depend on back-end implementation. In accordance with the illustrative embodiment, the signature is relatively simple such that a match indicates that such data may or may not be subject to further deduplication. This is because the lighter the hash algorithm is, the better in some cases because, as mentioned above, the cost of using more complex hash algorithms may not be worth the value they return. For example, a hash algorithm that returns a 16-bit hash will, in most cases, be sufficient. A 16-bit hash means that all data will be classified in 64K buckets, so even such a simple hash algorithm will proportionally simplify the data search and hash management. However, the invention does not preclude the use of more complex hash algorithms.

Once the hash has been calculated and the data and the hash have been saved in the controller DRAM device, the hash needs to be tracked. One way to accomplish this is to use a portion of the controller DRAM device as a hash array for storing the hash content. The hash content will reference a counter that will simply be incremented at the offset pointed to by the hash content. The value of the counter simply indicates the number of entries in the SSD cache device that contain data that produces the same hash and therefore may be a duplicate. It should be noted that the same hash may or may not indicate a duplicate as aliases are very possible, especially when relatively simple hashes are used. The counter will be incremented each time a hash entry is added and will be decremented each time a corresponding cache line is flushed to the PDs or dropped.

Because there is little or no additional latency resulting from the signature generation process, above criterion (1) is met. Because the signature generation process is an in-line process, it easily scales up with increasing IOPs, thereby meeting above criterion (2). In accordance with this illustrative embodiment, the back-end process occurs completely independently of the front-end process. The back-end process includes performing a dedupe algorithm, which may be identical or similar to existing back-end dedupe processes, except that the back-end process of this embodiment will first look to the hash corresponding to the line to be moved from the controller DRAM device into the SSD cache device and determine the value of the corresponding counter. If the value of the counter is equal to one, the process will simply skip any dedupe as there is none viable and proceed on a normal course of action without adding any more resource usage. If the value of the counter is greater than one, this means that there are other cache lines that may be duplicates, and therefore the process calls the back-end dedupe engine for further processing. At this point, the process has the cache ID or the data tag of the corresponding cache lines with the same hash, so no further hash processing is required. Therefore, existing back-end dedupe algorithms can be used to perform dedupe management by identifying if the data is actually a duplicate or not, and then managing it accordingly.

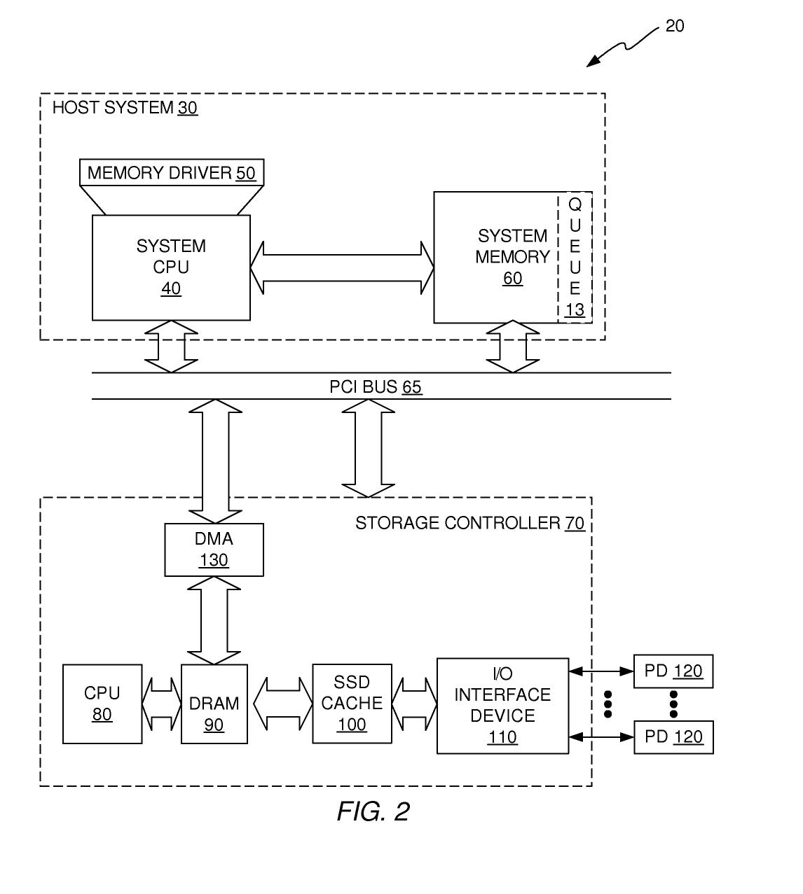

It should be noted that by performing the dedupe process in this manner, the data will not be written to the SSD cache memory device unless it has been determined that is not a duplicate. Therefore, the number of writes to the SSD cache device is reduced, which meets above criterion (3). All of these features and advantages will now be described with reference to a few illustrative embodiments depicted in FIGS. 2-8.

FIG. 2 illustrates a block diagram of a data storage system 20 in accordance with an illustrative embodiment. The system 20 includes a host system 30, a storage controller 70, a PCI or PCIe bus 65, and a plurality of PDs 120. The host system 30 includes a system CPU 40 and a system memory device 60. The storage controller 70 includes a CPU 80, a DRAM device 90, an SSD cache device 100, an I/O interface device 110, and a DMA engine 130. The I/O interface device 110 is configured to perform data transfer in compliance with known data transfer protocol standards, such as the SAS, SATA and/or NVMe standards. The I/O interface device 110 controls the transfer of data to and from the PDs 120. The storage controller 70 and the host system 30 communicate with each other via the PCI bus 65 and the DMA engine 130. The storage controller 70 and the host system 30 may also communicate with each other via the PCI bus 65 and the memory driver program 50 running on the system CPU 40. The system memory device 60 stores software programs for execution by the system CPU 40 and data.

In accordance with this illustrative embodiment, the DMA engine 130 moves write data and commands from the system memory device 60 into the controller DRAM device 90 via bus 65. In addition, the DMA engine 130 has cryptographic encoding capability, and thus is capable of performing a hash algorithm to produce the aforementioned signatures, or hashes. Thus, in accordance with this illustrative embodiment, the signatures are generated in-line as the DMA engine 130 moves data from the system memory device 60 into the DRAM device 90. As indicated above, the signatures could instead be generated in-line by the memory driver program 50 running on the system CPU 40.

In accordance with an illustrative embodiment, once the hash is calculated, the data and the associated hash are stored together at the same location in the controller DRAM device 90. Storing the data and the associated hash together allows the hash to be tracked. The hash and the associated data could instead be stored at separate locations, but if they are, there needs to be some way of later associating the hash and the respective data with each other. This can be accomplished in a number of ways, such as by saving the data at one location and saving the hash at another location along with the address of the location at which the data is saved. In accordance with the illustrative embodiment in which the data and the associated hash are stored together, a portion of the DRAM device 90 is used as an array for storing the hashes and the corresponding data.

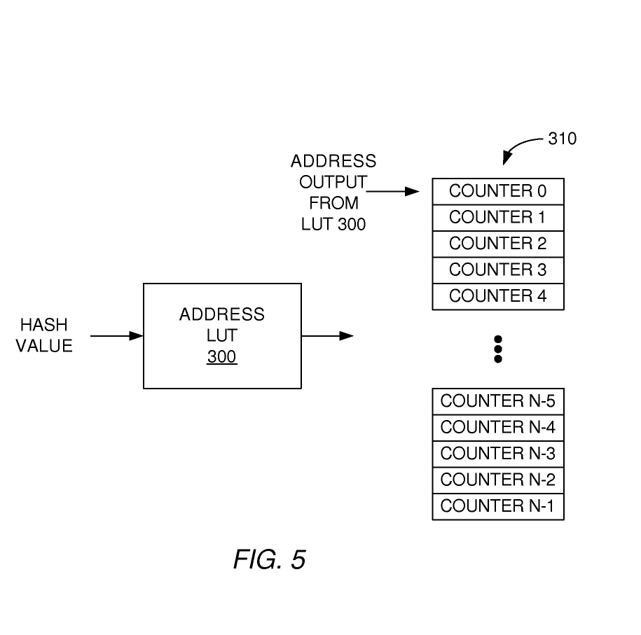

As will be described below in detail with reference to FIG. 5, each hash references a respective counter (not shown) that will be incremented or decremented by the controller CPU 80 under certain conditions and analyzed by the controller CPU 80 to make certain determinations. In general, the value of the counter indicates the number of data entries in the SSD cache 100 that produce the same hash and therefore may be duplicates. It should be noted that the same hash may or may not indicate a duplicate as aliases are very possible, especially when relatively simple hashes are used. The counter will be incremented when the associated hash is generated and will be decremented each time the corresponding cache line is flushed to the PDs 120 or dropped from the SSD cache device 100, as will be described below in more detail. In addition to incrementing the counter, the cache line, if available, or the IO tag of the DMA will typically be saved by the controller CPU 80 in the DRAM device 90 for further use by the back-end dedupe process.

The back-end dedupe process is typically performed by the controller CPU 80 in software, but could be performed by some other device, such as a dedicated dedupe engine (not shown). The controller CPU 80 first looks to the hash corresponding to the line to be moved from the controller DRAM device 90 into the SSD cache device 100 and determines the value of the associated counter. If the value of the counter is equal to one, the controller CPU 80 skips any dedupe process as there is none to be performed. If the value of the counter is greater than one, this means that there are other cache lines that may be duplicates, and therefore the CPU 80 performs the back-end dedupe algorithm. As indicated above, existing back-end dedupe algorithms may be used to perform dedupe management by identifying if the data is actually a duplicate or not, and then managing the data accordingly. The invention is not limited with respect to the back-end dedupe algorithm that is used for this purpose, as many dedupe algorithms exist that are suitable for this purpose.

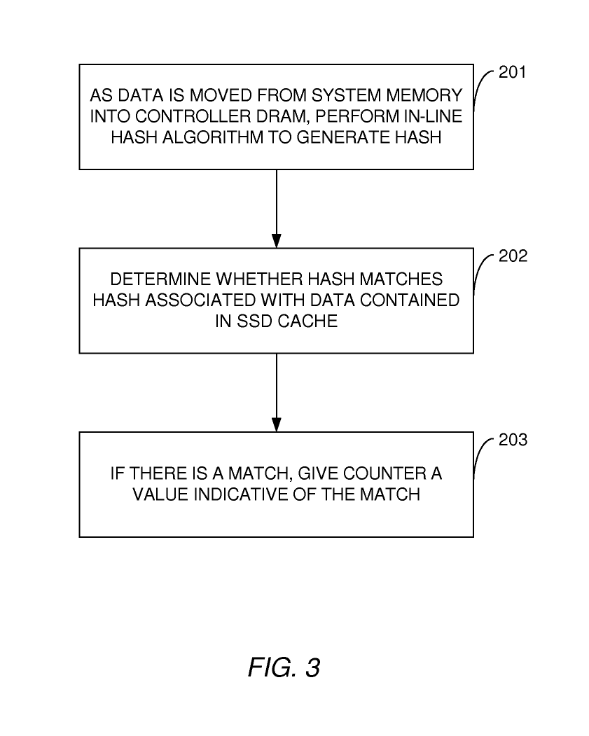

FIG. 3 is a flow diagram that generally represents the front-end portion of the dedupe process in accordance with an illustrative embodiment. As write data is moved from a system memory device into the controller DRAM device, an in-line hash algorithm is performed to generate a hash associated with the data, as indicated by block 201. After the hash has been generated, a determination is made as to whether the hash matches a hash associated with contents contained in SSD cache memory, as indicated by block 202. If so, a count associated with the hash is given a value indicative of the match, as indicated by block 203.

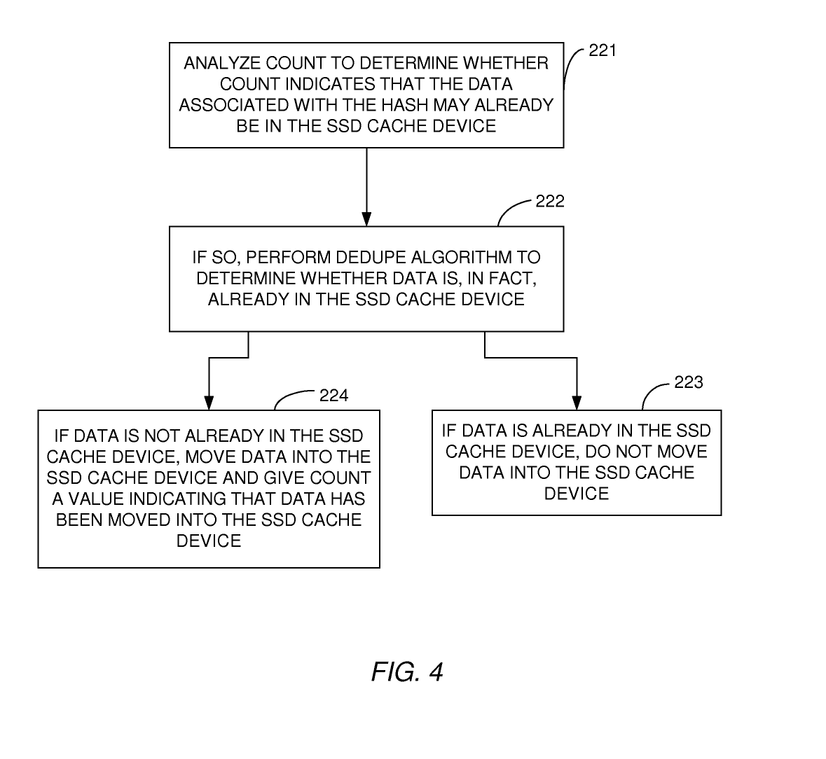

FIG. 4 is a flow diagram that represents the back-end portion of the dedupe process in accordance with an illustrative embodiment. Before data is moved from the controller DRAM device into the SSD cache device, a count associated with the hash that was generated from the data is analyzed to determine whether it indicates that the data may already be contained in the SSD cache device, as indicated by block 221. If so, a dedupe algorithm is performed to determine whether data is in fact already contained in the SSD cache device, as indicated by block 222. If the data is already in the SSD cache device, the data is not moved into the SSD cache device, as indicated by block 223. If the data is not already in the SSD cache device, the data is moved into the SSD cache device and a count associated with the hash of the data is given a value indicating that the data associated with the hash has been moved into the SSD cache device, as indicated by block 224.

FIG. 5 illustrates a block diagram of a lookup table (LUT) 300 and an array of count values 310 that are used in accordance with an illustrative embodiment to perform the front-end and back-end dedupe processes. The LUT 300 will typically be part of the controller CPU 80 or the controller DRAM device 90, but may be implemented at another location in the storage controller 70. The array of count values 310 is typically part of the DRAM device 90. The values stored at addresses of the array 310 are initially all zeros. After a hash has been generated, the hash is inputted to the LUT 300, which uses the hash to lookup an address of the DRAM device 90. The address that is output from the LUT 300 corresponds to one of N addresses of the array of count values 310, where N is a positive integer equal to the total number of hashes that are possible. For example, if each hash is a sixteen-bit number, then 2¹⁶=64K hash values are possible, where K=1024. Therefore, in this example N=64K. Each time a hash value is generated, the front-end algorithm performed by the controller CPU 80 obtains the corresponding address from the LUT 300, uses the address to access the corresponding count value of the array 310, reads the corresponding count value, increments the corresponding count value, and stores the new count value at the same address in the array 310.

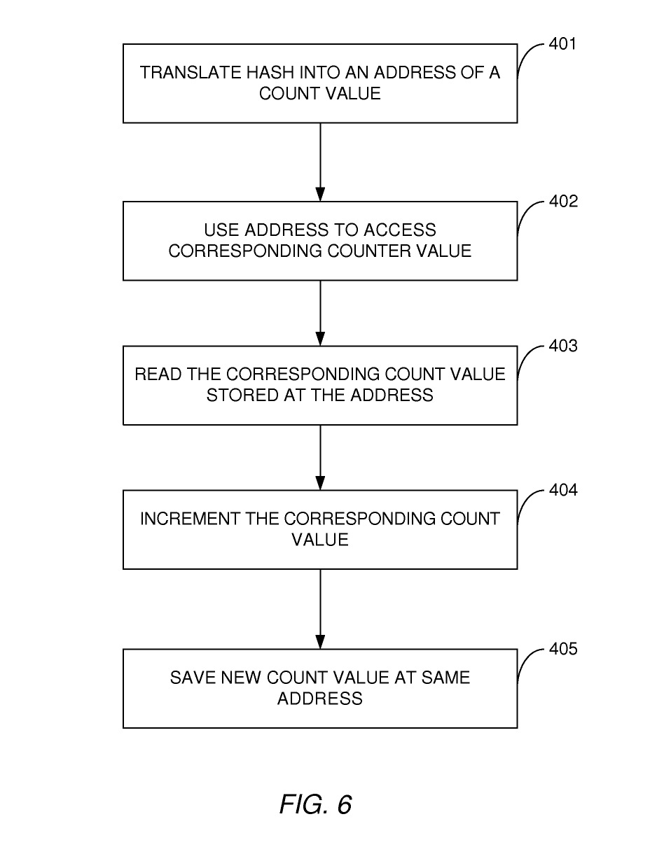

FIG. 6 is a flow diagram that demonstrates the front-end algorithm described above with reference to FIG. 5 performed by the controller CPU 80. Block 401 represents the step of using the LUT 300 to translate the hash into an address. Block 402 represents the step of using the address corresponding to the translated hash to access the corresponding count value in the array 310. Block 403 represents the step of reading the count value. Block 404 represents the step of incrementing the count value to produce a new count value. Block 405 represents the step of saving the new count value in the corresponding address in the array 310.

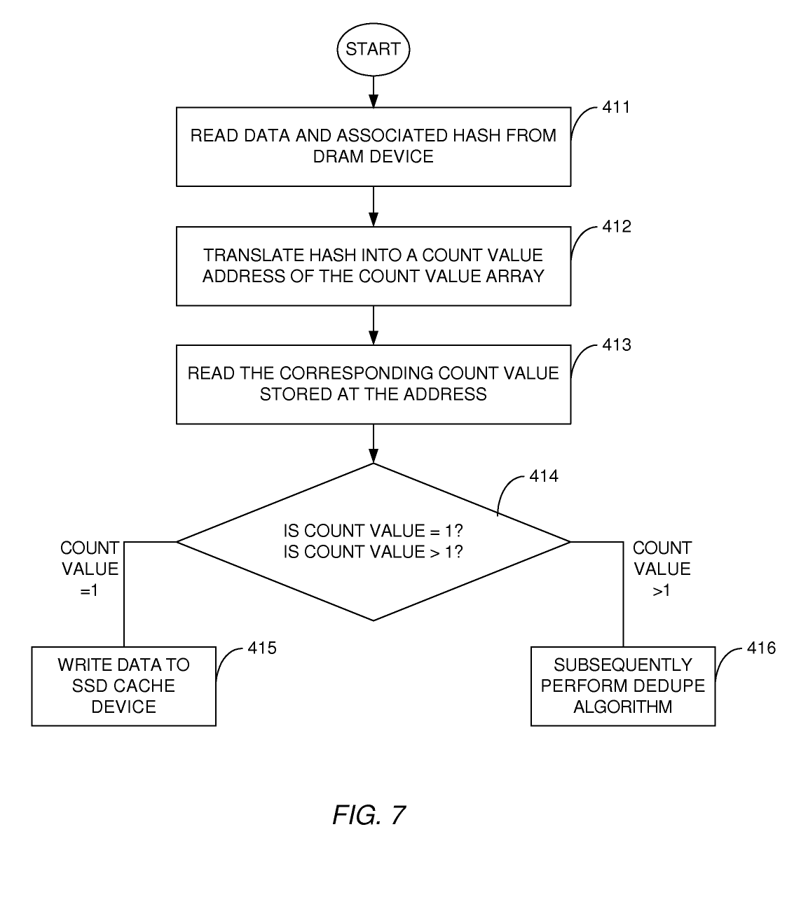

FIG. 7 illustrates a flow diagram of a first portion of the back-end algorithm in accordance with an illustrative embodiment that is performed by the controller CPU 80, which uses the count values stored in the array 310 to determine whether data stored in the controller DRAM device 90 is to be moved into the SSD cache device 100. When data is to be moved from the DRAM device 90 into the SSD cache device 100, the back-end algorithm reads data and the associated hash from the DRAM device 90, as indicated by block 411, and translates the hash into an address of the array 310, as indicated by block 412. The back-end algorithm then reads the corresponding count value from the array 310 of the controller DRAM device 90, as indicated by block 413. As indicated above, the data and the associated hash are typically stored at the same location in the DRAM device 90. Therefore, in that case, the data and the associated hash are read at the same time from the same location in the DRAM device 90. The hash is then translated by the LUT 300 into the address of the array 310 at which the corresponding count value is stored.

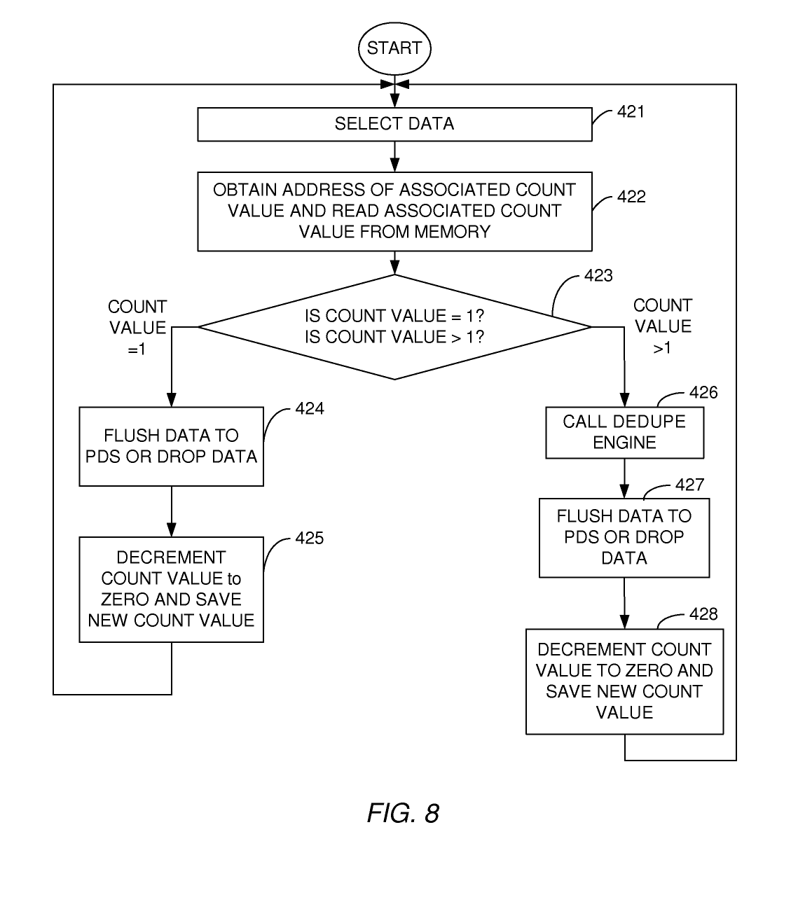

The back-end algorithm then determines whether the count value is equal to one or whether the count value is greater than one, as indicated by block 414. If the count value is equal to one, then the back-end algorithm causes the data to be written to the SSD cache device 100, as indicated by block 415. If the count value is greater than one, the dedupe algorithm will subsequently be performed to remove duplicates from the SSD cache device, as indicated by block 416. As indicated above, there are many existing back-end dedupe algorithms that are suitable for this purpose. The invention is not limited with respect to the particular dedupe algorithm that is used for this purpose. The only difference between the existing dedupe algorithm and the dedupe algorithm of the invention is that the dedupe algorithm of the invention is modified to use the count values and, if necessary, to modify the count values, as will now be described with reference to FIG. 8.

FIG. 8 illustrates a flow diagram of the off-line back-end process in accordance with an illustrative embodiment, which includes the modified dedupe algorithm. In accordance with this illustrative embodiment, the modified dedupe algorithm is performed off-line as part of the back-end process that reads data from the SSD cache device 100 and determines whether or not the data is to be flushed (i.e., written to the PDs 120) or dropped (i.e., identified as addresses in the SSD cache device that can be overwritten). Data that is “dirty” needs to be flushed, whereas data that is “clean” can be overwritten. Data in the SSD cache device 100 is deemed to be “dirty” if the data in the SSD cache device 100 and the corresponding data in the PDs 120 are not identical. Data is deemed to be “clean” if the data in the SSD cache device 100 and the corresponding data in the PDs 120 are identical.

As the back-end process analyzes data to determine whether it is to be flushed or dropped, it uses the addresses of the array 310 that were determined to be associated with the respective data when the process described above with reference to FIG. 7 was performed. In other words, the association between the data and the addresses at which the respective count values are stored is preserved so that it is not necessary for the back-end process to use the LUT 300 to translate each hash into an address in the array 310. Alternatively, the back-end process may perform the translation process again.

At the beginning of the process, data that is to be either flushed or dropped is selected, as indicated by block 421. The address of the count value associated with the data is determined and the count value is read from memory, as indicated by block 422. A determination is then made as to whether the count value is equal to one or whether the count value is greater than one, as indicated by block 423. If the count value is equal to one, the back-end process either flushes or drops the data, as indicated by block 424. The back-end process then decrements the count value to zero and saves the new count value, as indicated by block 425. The process then returns to block 421 at which the next cache line of data is selected.

If a determination is made at block 423 that the count value is greater than one, the back-end process calls a dedupe engine, as indicated by block 426. The dedupe engine determines whether the data is in fact duplicated in the SSD cache device and removes duplicates. After the duplicates have been removed, the single copy of the data remaining in the SSD cache device 100 is either flushed or dropped depending on whether the data is dirty or clean, as indicated by block 427. At some point during or after the sub-processes represented by blocks 426 and 427, the count value is decremented for each time the selected data is compared to data that produced the same hash value until the count value has been decremented to zero, as indicated by block 428. The process then returns to block 421 at which the next cache line of data is selected.

It should be noted that the flow diagrams of FIGS. 6-8 are merely illustrative of the overall functionality of the front-end and back-end processes and are not intended to demonstrate instruction-level, or code-level, processes. Persons of skill in the art will understand that the computer code for providing this functionality may be implemented in many different ways. Also, while the back-end processes represented by the flow diagrams of FIGS. 7 and 8 are depicted as being separate processes, this is merely for exemplary purposes. These processes can be combined into a single process.

The functionality of the host systems 30 and the storage controller 70 may be implemented in hardware, software, firmware, or a combination thereof. The computer code for implementing functionality in software or firmware is stored on a non-transitory computer-readable medium (CRM), such as system memory device 60 and DRAM 90 or some other memory device. The CRM may be any type of memory device including, but not limited to, magnetic storage devices, solid state storage devices, flash memory devices, and optical storage devices. Each of the CPUs 40 and 80 typically comprises at least one microprocessor, but may comprise any type of processor that is capable of providing the functionality that is necessary or desired to perform the associated tasks, including, for example, a microcontroller, a digital signal processor (DSP), an application specific integrated circuit (ASIC), and a system on a chip (SOC). The term “processor,” as that term is used herein, is intended denote these and other types of computational devices that may be programmed or configured to perform the tasks described above and any additional tasks that are deemed necessary to allow the CPUs 40 and 80 to perform their roles. In addition, the term “processor,” as that term is used herein, is also intended to denote computational devices that perform functions in hardware, such as state machines embedded in ICs.

It should be noted that the invention has been described with reference to a few illustrative, or exemplary, embodiments for the purposes of demonstrating the principles and concepts of the invention. As will be understood by persons of skill in the art, many variations may be made to the illustrative embodiments described above without deviating from the scope of the invention. All such variations are within the scope of the invention.

What is claimed is:

1. A data storage system comprising:
a host system comprising a system processor and a system memory device;
a storage controller comprising a controller processor, a controller dynamic random access memory (DRAM) device, and a solid state disk (SSD) cache device; and
a bus interconnecting the host system with the storage controller, wherein the data storage system performs a deduplication process comprising a front-end process and a back-end process, wherein the front-end process is an in-line process that is performed as data to be written is moved from the system memory device via the bus into the controller DRAM device, the front-end process comprising performing a signature generation algorithm on the data to generate a signature for the data and associating the signature with a respective count value, and wherein the back-end process comprises a deduplication process that uses the count value to perform deduplication.

2. The data storage system of claim 1, wherein associating the signature with a respective count value includes using the signature as a reference to an address at which the respective count value is stored.

3. The data storage system of claim 2, wherein the front-end process further comprises:
incrementing the respective count value to produce a new count value each time the signature generation algorithm generates a signature that matches the signature that the front-end process previously generated, wherein the matching signatures both reference said address, and wherein the new count value is stored at said address such that the previous count value is overwritten.

4. The data storage system of claim 3, wherein the back-end deduplication process analyzes the count value stored at said address to determine whether the count value indicates that the data associated with the signature may already be contained in the SSD cache device.

5. The data storage system of claim 4, wherein if the back-end deduplication process determines that the count value indicates that the data associated with the signature may already be contained in the SSD cache device, the back-end deduplication process determines whether the data associated with the count value is in fact already in the SSD cache device.

6. The data storage system of claim 5, wherein if the back-end deduplication process determines that the data associated with the count value is in fact already in the SSD cache device, the data stored in the controller DRAM device is not moved into the SSD cache device.

7. The data storage system of claim 5, wherein if the back-end deduplication process determines that the data associated with the count value is not in fact already in the SSD cache device, the data stored in the controller DRAM device is moved into the SSD cache device and the count value is decremented.

8. The data storage system of claim 1, wherein the storage controller further comprises a direct memory access (DMA) engine that performs the signature generation algorithm as the DMA engine moves the data from the system memory device into the controller DRAM device.

9. The data storage system of claim 1, wherein the system processor executes a memory driver software program that performs the signature generation algorithm as the memory driver program causes the data to be moved from the system memory device into the controller DRAM device.

10. A storage controller for use in a data storage system comprising a host system, the storage controller comprising:
a controller processor, a controller dynamic random access memory (DRAM) device, a solid state disk (SSD) cache device, the controller processor being configured to perform a deduplication process comprising a front-end process and a back-end process, wherein the front-end process is an in-line process that is performed as data to be written is moved from a system memory device of the host system into the controller DRAM device, the front-end process comprising performing a signature generation algorithm on the data to generate a signature for the data and associating the signature with a respective count value, and wherein the back-end process comprises a deduplication process that uses the count value to perform deduplication.

11. The storage controller of claim 10, wherein associating the signature with a respective count value includes using the signature as a reference to an address at which the respective count value is stored.

12. The storage controller of claim 11, wherein the front-end process further comprises:
incrementing the respective count value to produce a new count value each time the signature generation algorithm generates a signature that matches the signature that the front-end process previously generated, wherein the matching signatures both reference said address, and wherein the new count value is stored at said address such that the previous count value is overwritten.

13. The storage controller of claim 12, wherein the back-end deduplication process analyzes the count value stored at said address to determine whether the count value indicates that the data associated with the signature may already be contained in the SSD cache device.

14. The storage controller of claim 13, wherein if the back-end deduplication process determines that the count value indicates that the data associated with the signature may already be contained in the SSD cache device, the back-end deduplication process determines whether the data associated with the count value is in fact already in the SSD cache device.

15. The storage controller of claim 14, wherein if the back-end deduplication process determines that the data associated with the count value is in fact already in the SSD cache device, the data stored in the controller DRAM device is not moved into the SSD cache device.

16. The storage controller of claim 14, wherein if the back-end deduplication process determines that the data associated with the count value is not in fact already in the SSD cache device, the data stored in the controller DRAM device is moved into the SSD cache device and the count value is decremented.

17. The storage controller of claim 10, further comprising:
a direct memory access (DMA) engine that performs the signature generation algorithm as the DMA engine moves the data from the system memory device into the controller DRAM device.

18. A method for performing deduplication in a data storage system, the method comprising:
in a system memory device of a host system of the data storage system, storing data;
in the data storage system, moving the data from the system memory device into a controller dynamic random access memory (DRAM) device of a storage controller of the data storage system;
as the data is moved from the system memory device into the controller DRAM device, performing an in-line signature generation process on the data to generate a signature for the data and associating the signature with a respective count value; and
after the signature generation process has been performed, performing a back-end deduplication process that uses the count value to perform deduplication.

19. The method of claim 18, wherein associating the signature with a respective count value includes using the signature as a reference to an address at which the respective count value is stored.

20. The method of claim 19, wherein the front-end process further comprises:
incrementing the respective count value to produce a new count value each time the in-line signature generation process generates a signature that matches the signature that the front-end process previously generated, wherein the matching signatures both reference said address, and wherein the new count value is stored at said address such that the previous count value is overwritten.

21. The method of claim 20, wherein the back-end deduplication process analyzes the count value stored at said address to determine whether the count value indicates that the data associated with the signature may already be contained in the SSD cache device.

22. The method of claim 21, wherein if the back-end deduplication process determines that the count value indicates that the data associated with the signature may already be contained in the SSD cache device, the back-end deduplication process determines whether the data associated with the count value is in fact already in the SSD cache device.

23. The method of claim 22, wherein if the back-end deduplication process determines that the data associated with the count value is in fact already in the SSD cache device, the data stored in the controller DRAM device is not moved into the SSD cache device.

24. The method of claim 22, wherein if the back-end deduplication process determines that the data associated with the count value is not in fact already in the SSD cache device, the data stored in the controller DRAM device is moved into the SSD cache device and the count value is changed to indicate that the data has been moved into the SSD cache device.

25. The method of claim 18, wherein the storage controller further comprises a direct memory access (DMA) engine, and wherein the in-line signature generation process is performed by the DMA engine as the DMA engine moves the data from the system memory device into the controller DRAM device.

26. The method of claim 18, wherein the system processor executes a memory driver software program, and wherein the memory driver software program performs the in-line signature generation process as the memory driver software program causes the data to be moved from the system memory device into the controller DRAM device.

27. A non-transitory computer-readable medium (CRM) having a computer program stored thereon, the computer program comprising computer code for execution by one or more processors of a storage controller of a data storage system for performing deduplication in the data storage system, wherein as data is moved from a system memory device of the data storage system into a dynamic random access memory (DRAM) device of the storage controller, an in-line signature generation process is performed on the data to generate respective signatures for respective data, and wherein the computer program comprises:
a front-end code portion, wherein the front-end code portion includes computer code that associates each respective signature with a respective count value; and
a back-end code portion, wherein the back-end code portion includes computer code that performs a back-end deduplication process that uses the count values to perform deduplication.

28. The CRM of claim 27, wherein the computer code of the front-end code portion associates each respective signature with a respective count value by using each respective signature as a respective reference to a respective address at which the respective count value is stored.

29. The CRM of claim 28, wherein the front-end code portion further comprises:
computer code for incrementing the respective count value to produce a new count value each time a signature is generated that matches the signature that the signature generation process previously generated, and wherein the matching signatures both reference said address; and
storing the new count value at said address such that the previous count value is overwritten.

30. The CRM of claim 29, wherein the back-end code portion includes computer code that analyzes the count value stored at the address to determine whether the count value indicates that the data associated with the signature may already be contained in the SSD cache device.

31. The CRM of claim 30, wherein if the computer code of the back-end code portion determines that the count value indicates that the data associated with the signature may already be contained in the SSD cache device, the computer code of the back-end code portion determines whether the data associated with the count value is in fact already in the SSD cache device.

32. The CRM of claim 31, wherein if the computer code of the back-end code portion determines that the data associated with the count value is not in fact already in the SSD cache device, the computer code of the back-end code portion moves the data from the controller DRAM device into the SSD cache device and changes the count value to indicate that the data has been moved into the SSD cache device.
